(19) United States
(12) Patent Application Publication
(10) Pub. No.: US 2024/0232497 A1
(43) Pub. Date: Jul. 11, 2024

(54) Method for Generating Placement and Routing for an Integrated Circuit (IC)

(71) Applicant: RapidSilicon US, Inc, Los Gatos, CA (US)

(72) Inventors: Thierry Besson, Antibes (FR); Pierre-Emmanuel Gaillardon, Salt Lake City, UT (US)

(21) Appl. No.: 18/150,716

(22) Filed: Jan. 5, 2023

(51) Int. Cl. G06F 30/392; G06F 30/327; G06F 30/3315; G06F 30/394

(52) U.S. Cl. CPC G06F 30/392; G06F 30/327; G06F 30/3315; G06F 30/394

(57) ABSTRACT

A technology is described for generating placement and routing for a netlist of an integrated circuit (IC) design. The netlist for the IC design is partitioned into multiple subsets of cells. The subsets of cells are prioritized. Multiple stepwise place and route iterations are performed for the multiple subsets of cells. A first subset of cells with a first priority is placed in an arrangement representing the IC design. Wire connections are routed between the cells of the first subset of cells. A second subset of cells is placed relative to one another and the first subset of cells in the arrangement. Wire connections are routed between the cells of the second subset of cells and the cells of the first subset of cells.

### BACKGROUND

A semiconductor or integrated circuit (IC) has electronic circuits formed on conductors such as silicon. The IC may be a programmable logic device (PLD) with reconfigurable digital circuits with an undefined function at the time of manufacture. The PLD can have field-programmable gate arrays (FPGAs) designed to be configured by a customer or a designer after manufacturing.

Place-and-route (P&R) is a one stage in the design of printed circuit boards (PCBs), integrated circuits (ICs), and field-programmable gate arrays (FPGAs). P&R is done through two distinct, monolithic steps and in sequential order, namely 1) placement and then 2) routing. The first step, placement, involves deciding where to place all electronic components, circuitry, logic elements and/or cells or groups of such devices in a limited area. The second step, routing, involves deciding where to place the wires needed to connect the placed components, logic elements and/or cells while accommodating the limitations of the manufacturing process. With respect to integrated circuits, a layout of a larger block of the circuit (or the entire circuit) is created from layouts of smaller sub-blocks. With respect to field-programmable gate arrays (FPGAs), components, logic elements, or cells or groups thereof, are placed and interconnected on the grid of the FPGA.

The P&R operation or run is usually performed by electronic design automation (EDA) tools. The result of the P&R operation is the “layout”, a geometric description of the location and rotation of each part, and the path of each wire connecting them. A complete P&R run that can take a relatively long time. In addition, an IC operating frequency can be determined by the P&R run. Again, a designer must wait a relatively long time to find if the operating frequency is acceptable.

### BRIEF DESCRIPTION OF THE DRAWINGS

FIG. 1 is a block diagram illustrating an example of a stepwise place-route (SPR) process for placing and routing subsets of cells.

FIG. 2a is a flowchart illustrating an example of a method of generating stepwise placement-routing (SPR) for a netlist of an integrated circuit (IC).

FIG. 2b is a flowchart illustrating an example of a method of generating stepwise placement-routing (SPR) of FIG. 2a.

FIG. 3a is a flowchart illustrating an example of a method of generating stepwise placement-routing (SPR) for a netlist of an IC including calculating frequency.

FIG. 3b is a flowchart illustrating an example of a method of generating stepwise placement-routing (SPR) of FIG. 3a.

FIG. 4 is a flowchart illustrating an example of a method of generating stepwise placement-routing (SPR) for a netlist of an IC including varying the subsets.

FIG. 5 is a flowchart illustrating an example of a method of generating stepwise placement-routing (SPR) for a netlist of an IC including changing the cost function or selecting a new cost function.

FIG. 6 is a flowchart illustrating an example of a method for generating stepwise placement-routing (SPR) for a netlist of an integrated circuit (IC).

FIG. 7 is a block diagram that provides an example illustration of a computing device that can be employed in the present technology.

### DETAILED DESCRIPTION

Reference will now be made to the examples illustrated in the drawings, and specific language will be used herein to describe the same. It will nevertheless be understood that no limitation of the scope of the technology is thereby intended. Alterations and further modifications of the features illustrated herein, and additional applications of the examples as illustrated herein, which would occur to one skilled in the relevant art and having possession of this disclosure, are to be considered within the scope of the description.

As described earlier, traditional place-and-route (P&R) is a two-step process with placing and routing happening separately and sequentially. P&R is done through two distinct, monolithic steps and in sequential order, namely first placement and then routing.

In the placement step, the components or cells can be placed according to cost functions that are desired to be minimized. The cost functions can estimate, as much as possible, the “cost” of all the nets needed to connect the cells. This is an estimation because the wiring depends upon the routing phase after the placement is done. The cost of wiring reflects the area used to make the wiring possible and the timing delay to connect the cells (inter-connect delay), which influences the area and performance (clock frequencies) of the design. These cost functions try to estimate the “best” placement so that during routing the criteria considered—area used for wiring, inter-connect delays—are minimized. A typical cost function is the Half-Perimeter Bounding Box (HPBB) of a net or connection and at the design level the sum of the HPBB (and average HPBB per net or connection). It is desirable to minimize the sum of the HPBB and it is believed that minimizing this function has a good/correct correlation regarding the criteria to be minimized.

The route step may be constrained by the placement of the components or cells that are fixed in place. If the placement was poor or if the cost function was not accurate enough, then the routing can deviate from what was projected by the cost function in term of used wire area, nets congestion, inter-connect delays and final clock frequencies.

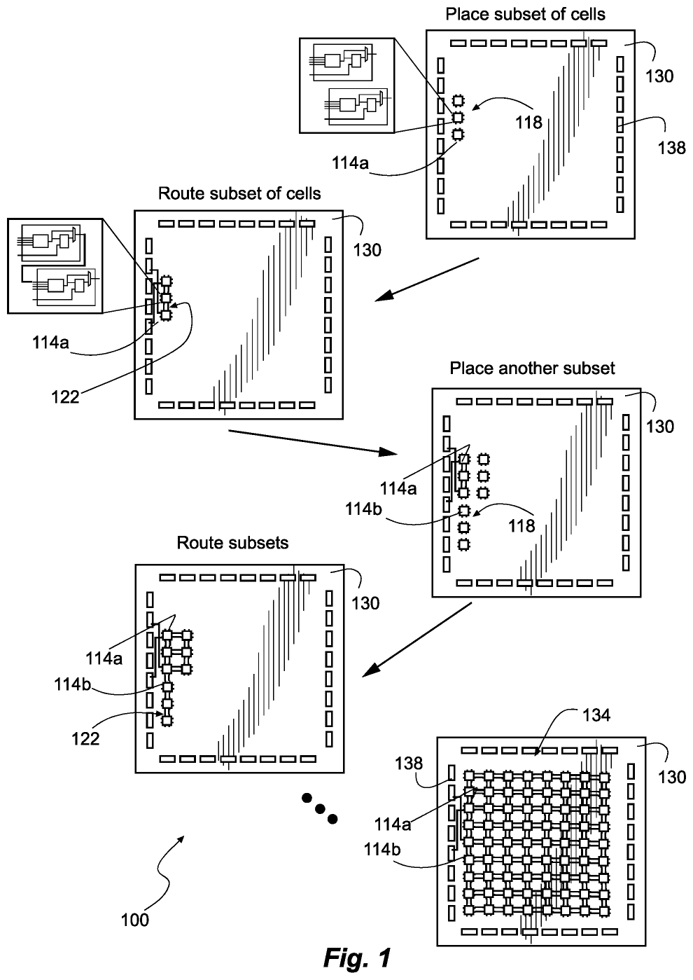

The present technology relates to an improvement for integrated circuit (IC) design and a method for generating placement and routing for a netlist. Namely, the two steps, place and route, are combined and applied on portions or subsets of the design in a sequence of multiple “place-route” calls or actions to complete the full placement-and-routing. FIG. 1 depicts an example block diagram illustrating the sequential, interleaved, or stepwise placement and routing (SPR) 100 of the present technology. A first subpart or subset 114a of the design is placed 118 and then the wires are routed 122 in the arrangement 130 representing the sub-part of the IC design, then a second subpart or subset 114b is placed 118 and then wires are routed 122, and so on until the whole design or arrangement 134 is stepwise placed-and-routed. (The term “SPR” may be used to refer to the stepwise place-route applied on a small piece of logic instead of the traditional “P&R” applied on the whole netlist.)

The present stepwise place-route (SPR) approach has several benefits, including better quality of results (QoR), such as timing, in cases when timing distribution within the design would have otherwise been unbalanced. For example, a design can be unbalanced when it has very high critical timing regions and low critical timing regions.

As described above, one problem with the classical P&R approach is that placement has freedom to place cells anywhere but lacks an accurate cost function. So, placement typically tries to guess a “good” placement where “good” is based on a guessing cost function. Whether or not the placement is actually good or not is unknown until the routing is completed. For instance, the sum of HPBB should consider all cells, even the least critical ones. In order to correct this, some weight might be placed on the critical cells for HPBB, but it is difficult to guess the weights to select because there is no accurate timing yet.

Routing, on the other hand, can have an accurate cost function because it deals with real physical wires and delays, but in the past, there was no freedom regarding the physical locations of the cells after the cells were fixed in place. Previously, routing has dealt with a hyper-constrained problem and has a very small degree of freedom despite having an accurate cost function. Routing can only route wires, once the cells are fixed in place.

The present stepwise place-route (SPR) approach merges the two processes to get the best aspects of both place and route, namely, to get more freedom of decision through the process and to make the decision with better accuracy. With the sequence of stepwise place-routes (SPRs) the approach is refined by mixing the accurate cost function from routing into the placement decisions in a stepwise process. By stepwise placing-routing (SPR) a subpart of the design, accurate timing is known right away and the resources used (cells and routing wire) are known before the stepwise placement-routing (SPR) of the next subpart of the design is addressed. This incremental and accurate timing information, that is building up along the process, can better drive the future stepwise placement-routing (SPR) steps. The current best frequency is known at each step and each subsequent stepwise placement-routing (SPR) can try and preserve the best frequency. This best frequency may have been obtained in the best conditions at the very first step by focusing on the most critical part of the design when all the resources were available. As the process progresses, less resources are available (e.g., less layout area). But if the remaining cells have less criticality, then placing them on an arrangement that is already partially filled are less likely to hurt the current frequency being obtained. This approach may not help if the remaining cells to stepwise place-route (SPR) are also very critical. But this approach may work well when there is a clear disparity of timing criticality in portions the design.

Another benefit of the present stepwise place-route (SPR) approach is fast feedback information. By stepwise placing-routing (SPR) a small “chunk” of logic, or a subset of cells, some feedback information can be obtained right away instead of waiting for the whole placement process to complete and then the whole routing process to complete. Sometimes, traditional place-and-route (P&R) can take hours for designs with difficult timing constraints to meet.

By choosing to stepwise place-route (SPR) the expected most critical sub-part or subset of the design, it is possible to receive immediate feedback on the best expected frequency that can be achieved with that placement and routing portion. For example, the most critical sub-part of the design can be obtained from static timing analysis (STA). STA can determine what sub-part(s) of the design is/are expected to be the critical timing sections. These critical timing sections may be ranked according to their importance.

The best expected frequency for a first cell placement can be an upper bound because there is no reason to expect better performance in later steps because there are less constraints on the placer earlier on (i.e. when the placer has full empty space so all resources are still available). This frequency is the frequency expected in the best case; so, it should be an upper bound. For instance, a portion (e.g. 15%) or sub-part of the design that is considered critical can be stepwise placed-routed (SPR) initially and the upper bound frequency can be known upon performing that initial placing and routing, without the need to wait for the whole placement and then the whole routing (P&R). If the stepwise place-route (SPR) determines a 200 Mhz frequency on the first 15% critical sub-part, it is not possible to do better in later SPR steps. This can give the designer quick feedback and can be very valuable. For example, the designer can interact quickly with different stepwise place-route (SPR) scenarios, and/or different SPR partitions, without the need to wait for the whole place-and-route (P&R) process to complete on the whole design.

In addition, it is possible to leverage parallelism that can lead to automatic timing closure. By partitioning the design into small chunks of logic, or sub-parts, and stepwise place-route (SPR) the sub-parts, it is possible to do automatic explorations of stepwise place-route (SPR) sequences.

In one aspect, a basic algorithm could:
sort all the cells or sub-parts according to static timing analysis (STA) criticality (e.g. worst negative slacks first);
take the N first cells in the order and stepwise place-route (SPR) the cells;
determine an upper bound frequency for the N first cells; and
continue with next chunk or sub-part of cells from N+1 cell to M cell and stepwise place-route (SPR) those cells.

One way to determine the best N and M could be to do some exploration by taking several different values for N and run in the stepwise place-routes (SPRs) for each cut. Then for each cut result, perform the same process with different values of M.

For example, for a design of 500K cells with 15% negative slacks, the process may comprise taking:
the sub-parts with the 5% worst negative slack and stepwise place-route (SPR) them, then continue with the remaining sub-parts (i.e. taking the next 5% or the next 10%, etc.);
the sub-parts with the 10% worst negative slacks and SPR them, then continue;
the sub-parts with the 15% worst negative slacks and SPR them, then continue; and
the sub-parts with the 20% worst negative slacks and SPR them, then continue.

There can be an exploration tree on the partitions that should be faster than a classical place-and-route (P&R) approach. At the end, the solution can be:
take first 5% worst timing cells then SPR them (upper bound frequency=250 Mhz at the end of first SPR);
take 10% next worst cells then SPR them (frequency down to 235 Mhz);
take the 15% next worst cells then SPR them (frequency down to 230 Mhz); and
take the remaining 70% cells and SPR them (frequency stays at 230 Mhz).

The design is completely stepwise placed-routed (SPR) and the final frequency is 230 Mhz, or 20 Mhz under the upper bound frequency (250 Mhz). During this exploration, the designer can see the starting frequency and see how it evolves as chunks or subsets of logic are processed with stepwise place-route (SPR). In the previously existing P&R approach, the designer will only get the frequency of the electronic design at the very end, after a complete place-and-route (P&R) run of the whole design that can take quite some time. The present stepwise place-route (SPR) works on a sequence of relatively small chunks or subsets of logic, and the process can be relatively fast.

Another benefit of the present stepwise place-route (SPR) approach is better user interactivity that can lead to faster manual timing closure. The designer can define what the partition size to stepwise place-route (SPR) may be, especially the first sub-parts which are supposed to take care of the most timing critical cells. The designer can stepwise place-route (SPR) the partition and eventually can drive the SPR with some directives. For example, the directives can include stepwise place-route (SPR) only the clock domain which is only 20% of the design, stepwise place-route (SPR) logic A or sub-part B with this input-output (IOs) placement, and/or place 10% worst timing cells within a desired area of the arrangement. This allows the designer to have better control of the placement by doing this stepwise place-route (SPR) sequence by himself/herself in case timing constraints are very difficult to meet. The designer can then iteratively stepwise place-route (SPR) the design chunk-by-chunk, or subset-by-subset, until stepwise placing-routing (SPR) the whole design. At each stepwise place-route (SPR) iteration, the designer can get timing data feedback and/or analysis and decide what to do next. The designer may decide to continue, revisit RTL or synthesis related to that subset of logic because it is too far from the target clock frequency, revisit previous SPR-ed subsets of logic, etc.

Partitioning can be based on various cost functions in addition to STA-derived criticality. For example, partitioning can be done topologically with a machine learning (ML) process like k-means clustering to group local interconnects together, identify native partitions in the design or to group cells together that are better placed together. In addition, machine learning can be used to extract critical partitions early in the SPR process. In another configuration, a dataset of partitions can be generated using the criteria described above, and the criticality of a partition can be evaluated (also based on set of criteria) using an ML classifier to rank which partitions to start applying the SPR process to.

The ranking of partitions can be extended to nested partitions, whose criticality gets reevaluated at every (or a few) iterations of the loop. For example, a design can have 3 partitions: P1, P2, and P3. C(P1)>C(P2)>C(P3) with C being the criticality based on the criteria above. Then the approach will start SPR for the first partition P1, then will move to SPR for the second partition P2. The next natural move would be to go to SPR for the third partition P3, but a nested partition P1/2 can be created by combining P1 and P2 and the nested partition P1/2 can be considered. The nested partition P1/2 does have nets or connections between the two to be routed, and the individual SPRed partitions P1 and P2 could be placed relatively one to another. Then it is possible that C(P1/2)>C(P3). In that case, P1/2 could be escalated before moving to P3 and finishing with the top remaining SPR for P1/2/3.

The notion of the maximum frequency evaluated from the SPR of the most critical section is useful and can be used to extend a no-human-in-the-loop context. A previously existing P&R tool could take some timing constraints up front (such as Synopsis design constraints SDC) and apply it to the STA alongside with the design to understand the critical path. In an alternative mode, the “hardest portion to P&R” is first evaluated and used to percolate timing constraints to other blocks in a ripple fashion.

In summary, the present technology presents interleaving sequences for stepwise placing-routing (SPR) of chunks or subsets of the netlist. The subsets of the netlist can be prioritized for SPR based on a criteria, such as high timing critical paths, negative slack, clock domain, etc. Initial timing can be determined before stepwise placing-routing (SPR) additional subsets to obtain an upper bound case with the best expected frequency. Different sequences of stepwise placement-routing (SPR) of subsets can be explored concurrently by considering different ways of partitioning subsets of critical logic.

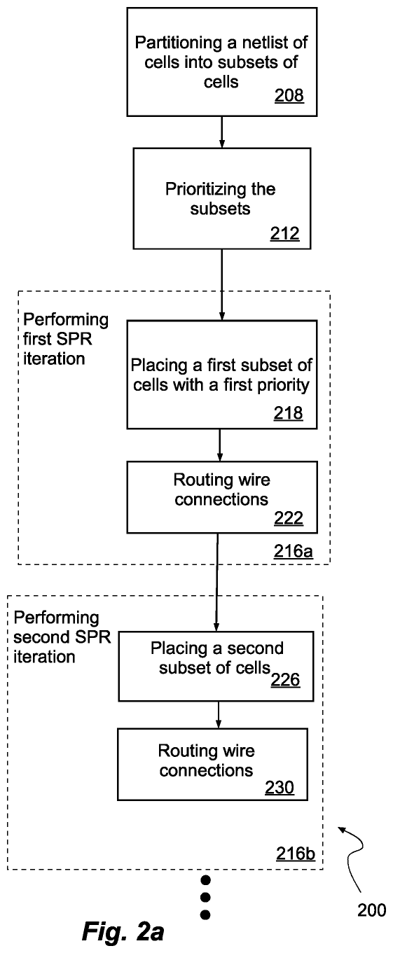

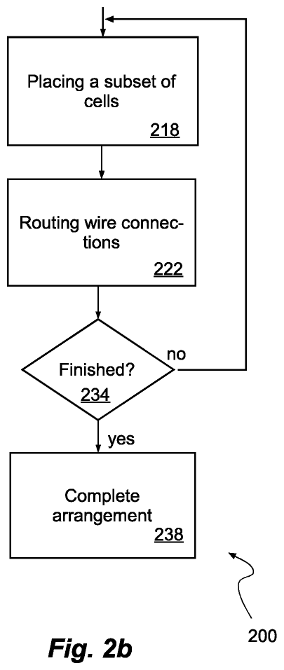

FIG. 2a depicts an example of a method 200 of generating stepwise placement and routing (SPR) for a netlist of an integrated circuit (IC) design. The IC design can comprise a field-programmable gate arrays (FPGAs) and the cells can comprise logic blocks and memory elements. The netlist can be synthesized from a register transfer level (RTL) description of the IC. The netlist can be a description of the connectivity of cells in the IC and can have a list of the electronic components, such as gates, in the IC and a list of their connections. The netlist can have different transformations applied to the netlist comprising at least one of: retiming or optimizations.

The method 200 can comprise partitioning 208 the netlist for the IC design into chunks or subsets of cells 114a and 114b (FIG. 1). Each subset of cells can contain a portion of the logic of the netlist for the IC. In one aspect, the partitioning can be based on machine learning (ML) with an ML classifier that may rank subsets of cells from a subset of cells represented by the entire netlist.

The subsets of cells can be prioritized 212. In one aspect, the subsets of cell can be prioritized 212 based at least in part on a cost function. For example, and as described above, the cost function can comprise static time analysis (STA) derived criticality based on negative slacks. As another example, the subset of cells can be prioritized topologically with k-means clustering to cluster local interconnects together and identify native partitions. As another example, the cost function can comprise parts of the domain with a common clock domain. As another example, the cost function can comprise input/output (IO) placement.

A first stepwise place-route (SPR) iteration can be performed 216a. A first subset of cells 114a (FIG. 1), with a first priority, can be placed 218 in an arrangement 130 (FIG. 1) representing the IC design. In one aspect, the first subset of cells 114a can be placed 218 relative to one another and relative to input/output (I/O) elements 138 (FIG. 1). The first subset of cells 114a can be routed 222 with wire connections between the cells of the subset of cells 114a and/or I/O elements 138 (FIG. 1). In one aspect, routing 222 can comprise routing the wire connections between components of the cells, and between the cells of the first subset of cells 114a.

A second stepwise place-route (SPR) iteration can be performed 216b. A second subset of cells 114b (FIG. 1), with a second priority, can be placed 226 in the arrangement 130 (FIG. 1). The second subset of cells 126 can be placed 226 relative to one another and the first subset of cells 114a. Placement 226 of the second subset of cells 114b occurs after placing 218 and routing 222 the first subset of cells 114a. The second subset of cells 114b can be routed 230 with wire connections between the cells of the second subset of cells 114b and the cells of the first subset of cells 114a. Multiple stepwise place-route (SPR) iterations can be performed as described above.

FIG. 2b depicts a further example of the method 200 with respect to FIG. 2a, but where the subsets of the cells 114a and 114b (FIG. 1) can be repeatedly 234 placed 218 and routed 222 with previously placed and routed subsets of cells until the arrangement 130 (FIG. 1) is complete 238.

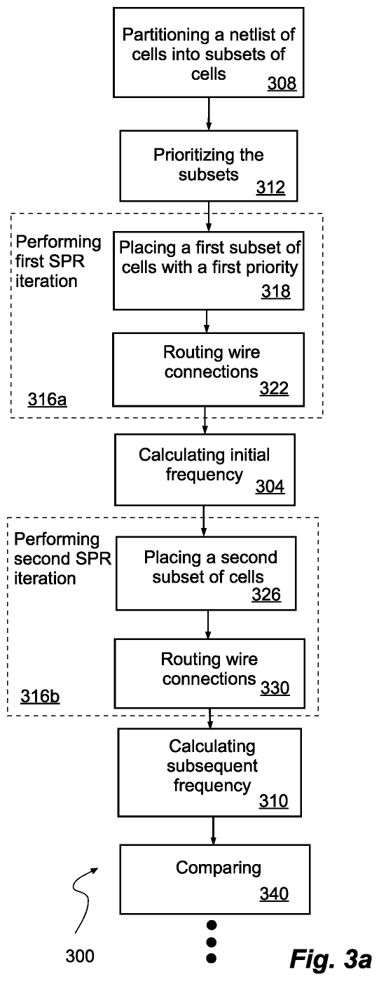

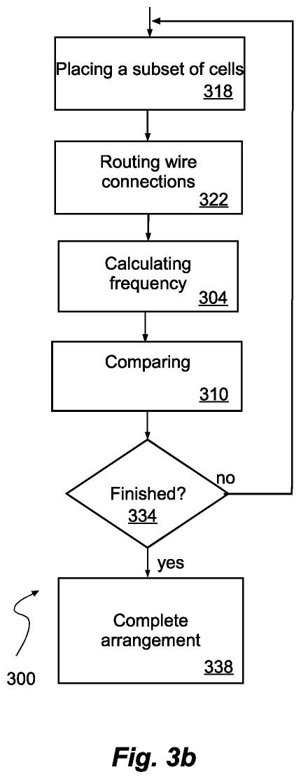

FIG. 3a depicts an example of a method 300 where an initial frequency of the IC design can be calculated 304 based on the first subset of cells 114a (FIG. 1) after placing 318 and routing 322 the first subset of cells 114a and prior to placing 326 and routing 330 the second subset of cells 114b (FIG. 1). The initial frequency of the first subset of cells 114a represents or defines an upper bound frequency or best-case frequency. In one aspect, a subsequent frequency of the IC design can be calculated 306 based on the first and second subsets of cells 114a and 114b after placing 326 and routing 330 the second subset of cells 114b. The subsequent and upper bound frequencies can be compared 340 to determine if the subsequent frequency has been degraded below a predetermined limit. The first and second stepwise place-route (SPR) iterations 316a and 316b can comprise calculating 304, 306 the initial and subsequent frequencies, respectively. Indeed, each stepwise place-route (SPR) iteration 316a and 316b can comprise calculating 304, 306 a cumulative frequency and comparing 310 the cumulative frequency to the initial upper bound frequency. As described previously, this can give the designer quick feedback. For example, the designer can interact quickly with different stepwise place-route (SPR) scenarios, and/or different SPR partitions, without the need to wait for the whole place-and-route (P&R) process to complete on the whole design. The steps of partitioning 308 and prioritizing 312 were described previously with respect to FIGS. 2a and 2b.

FIG. 3b depicts a further example of the method 300 with respect to FIG. 3a, but where the frequency of the IC design can be calculated 304 after each place 318 and route 322 and compared 310 with the upper bound frequency and/or a specification frequency to determine if the arrangement is within design specifications. The steps of repeatedly 334 placing 318 and routing 322 until the arrangement 130 (FIG. 1) is complete 338 were described previously with respect to FIGS. 2a and 2b.

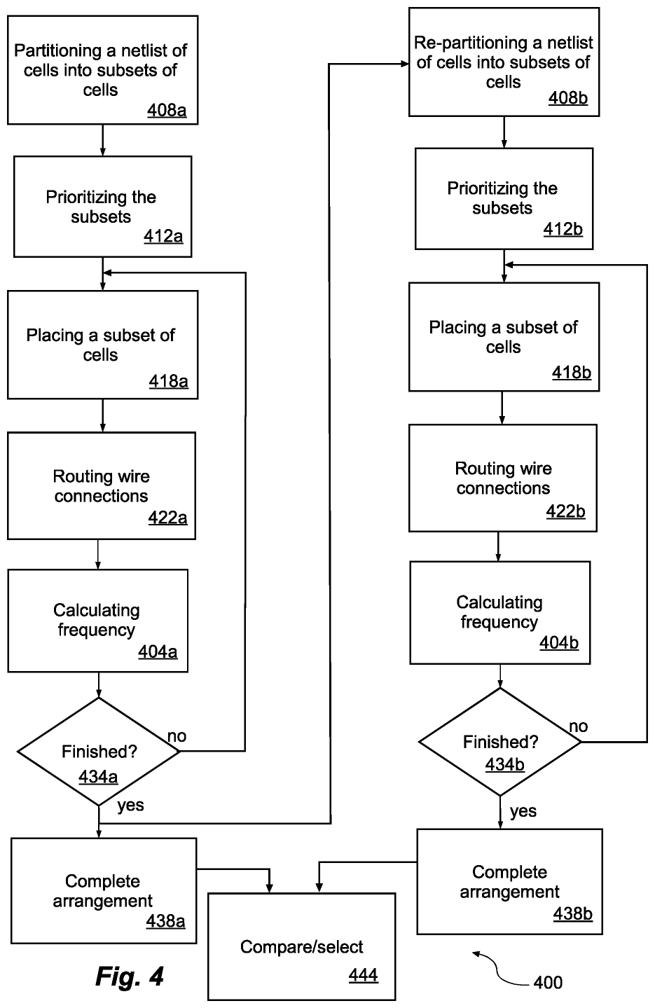

FIG. 4 depicts an example of a method 400 where the arrangement can be optimized by comparing the first arrangement 438a with one or more new arrangements 438b created with different subsets of cells or separating the same netlist using different sub-divisions. In one aspect, the new subsets of cells can have a different number of subsets of cells than before or with respect to the subset of cells of the first arrangement 238. In another aspect, the new subsets of cells can have different sizes than before or with respect to the subset of cells of the first arrangement 438a. In another aspect, the new subsets of cells can have both a different number or subsets and different sized subsets. For example, the first arrangement 438a may have 21 subsets of cells, each with 23 components; while the second arrangement 438b may have 23 subsets of cells, each with 21 components. Thus, the new subsets of cells can have a different partitions or arrangements than the first subsets of cells. The steps of partitioning 408b, prioritizing 412b, placing 418b, routing 422b, and calculating 404b can be repeated 434b with the new subsets of cells to form and define the second arrangement 438b. A cumulative frequency of the IC design can be calculated 404a based on the first arrangement 438a after placing 418a and routing 422a the first subset of cells. A new cumulative frequency of the IC design can be calculated 404b based on the new arrangement 438b after placing 418b and routing 422b the new subset of cells. The first and second arrangements 438a and 438b can be compared and one can be selected 444 based in part on the arrangement with the better frequency. In another aspect, the arrangement 304 or 404 can be selected 444 based on a fastest cumulative of the first or second arrangement 304 or 404. The steps of partitioning 408a, prioritizing 412a, placing 418a, routing 422a, calculating 404a, repeating 434a were described previously.

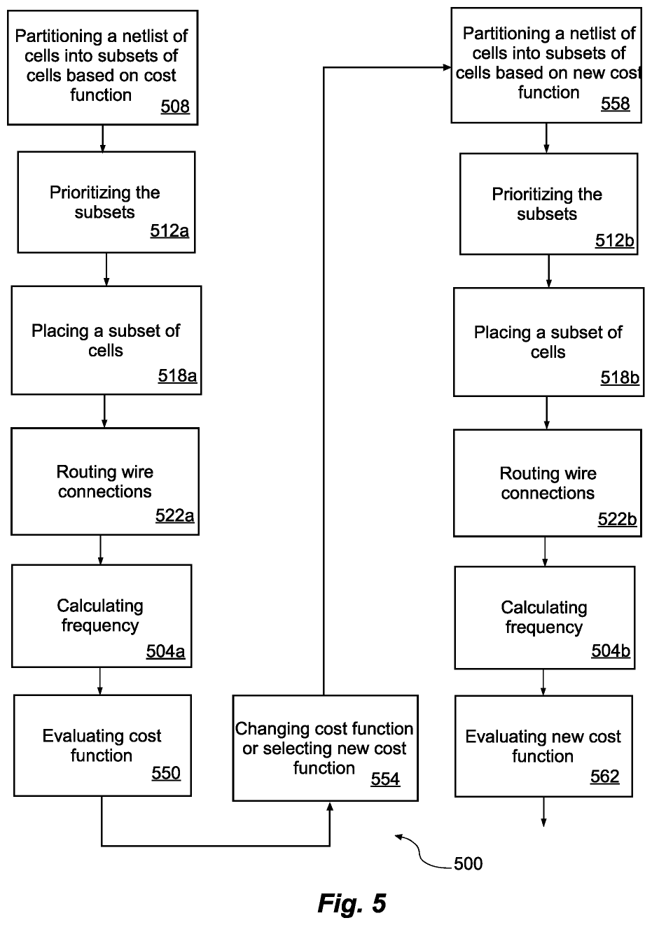

FIG. 5 depicts an example of a method 500 where the cost function can be evaluated and/or optimized. As described above, the netlist can be partitioned 508 based on a cost function. The cost function can be evaluated 550, and/or the placing 518a and routing 522a based on the cost function, after placing 518a and routing 522a one or more subsets of cells. The cost function can be changed 554 or a new cost function can be selected after placing 518a and routing 522a one or more subsets of cells to determine if the changed 554 or new cost function results in a faster frequency. All or some of the subsets of cells can be re-partitioned 558 based on the changed cost function or the new cost function. The changed cost function or the new cost function can be evaluated 562 after placing 518b and routing 522b the one or more subsets of cells if a faster frequency is achieved. The steps of prioritizing 512a and 512b an calculating the frequency 504 and 504b were described previously.

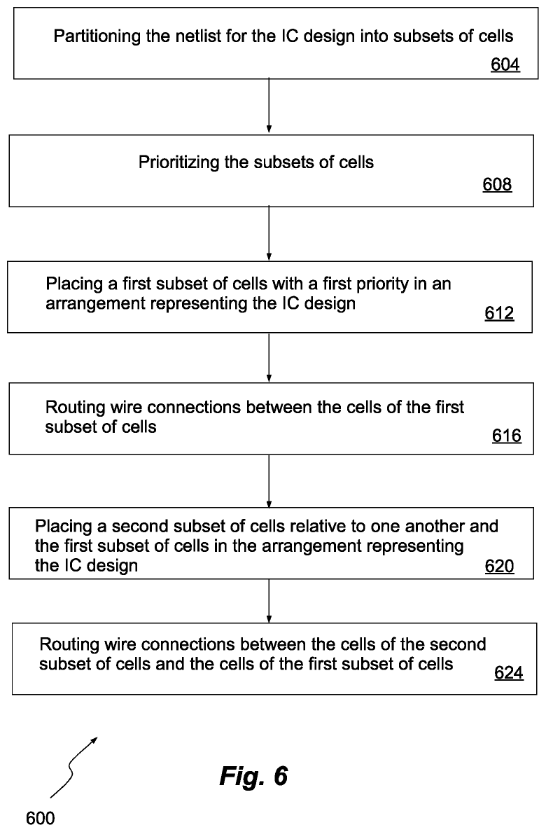

In summary, FIG. 6 depicts an example of a method 600 of generating placement and routing for a netlist of an integrated circuit (IC) design. The method 600 comprises partitioning the netlist for the IC design into subsets of cells, as in block 604. In addition, the method comprises prioritizing the subsets of cells based in part on a cost function, as in block 608. Another operation may be placing a first subset of cells with a first priority in an arrangement representing the IC design, as in block 612. The wire connections may be routed between the cells of the first subset of cells, as in block 616. In addition, the method 600 comprises placing 620 a second subset of cells relative to one another and the first subset of cells in the arrangement representing the IC design. Furthermore, the method 600 comprises routing 624 wire connections between the cells of the second subset of cells and the cells of the first subset of cells.

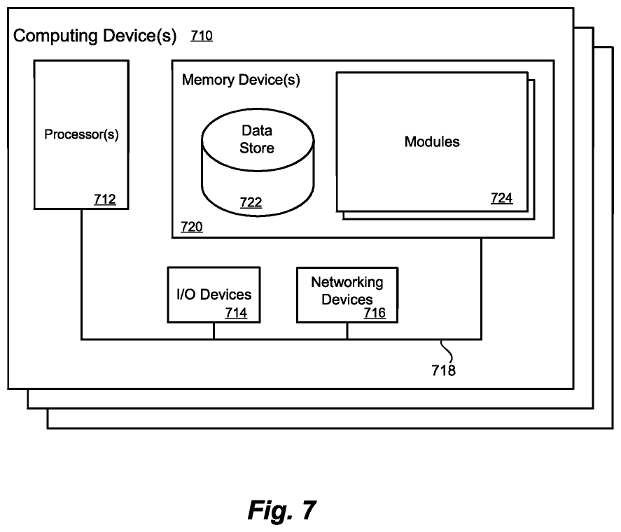

FIG. 7 illustrates a computing device 710 which may execute the foregoing subsystems of this technology. The computing device 710 and the components of the computing device 710 described herein may correspond to the servers and/or client devices described above. The computing device 710 is illustrated on which a high-level example of the technology may be executed. The computing device 710 may include one or more processors 712 that are in communication with memory devices 720. The computing device may include a local communication interface 718 for the components in the computing device. For example, the local communication interface may be a local data bus and/or any related address or control busses as may be desired.

The memory device 720 may contain modules 724 that are executable by the processor(s) 712 and data for the modules 724. For example, the memory device 720 may include an inflight interactive system module, an offerings subsystem module, a passenger profile subsystem module, and other modules. The modules 724 may execute the functions described earlier. A data store 722 may also be located in the memory device 720 for storing data related to the modules 724 and other applications along with an operating system that is executable by the processor(s) 712.

Other applications may also be stored in the memory device 720 and may be executable by the processor(s) 712. Components or modules discussed in this description that may be implemented in the form of software using high programming level languages that are compiled, interpreted or executed using a hybrid of the methods.

The computing device may also have access to I/O (input/output) devices 714 that are usable by the computing devices. An example of an I/O device is a display screen that is available to display output from the computing devices. Other known I/O device may be used with the computing device as desired. Networking devices 716 and similar communication devices may be included in the computing device. The networking devices 716 may be wired or wireless networking devices that connect to the internet, a LAN, WAN, or other computing network.

The components or modules that are shown as being stored in the memory device 720 may be executed by the processor 712. The term “executable” may mean a program file that is in a form that may be executed by a processor 712. For example, a program in a higher-level language may be compiled into machine code in a format that may be loaded into a random-access portion of the memory device 720 and executed by the processor 712, or source code may be loaded by another executable program and interpreted to generate instructions in a random-access portion of the memory to be executed by a processor. The executable program may be stored in any portion or component of the memory device 720. For example, the memory device 720 may be random access memory (RAM), read only memory (ROM), flash memory, a solid-state drive, memory card, a hard drive, optical disk, floppy disk, magnetic tape, or any other memory components.

The processor 712 may represent multiple processors and the memory 720 may represent multiple memory units that operate in parallel to the processing circuits. This may provide parallel processing channels for the processes and data in the system. The local interface 718 may be used as a network to facilitate communication between any of the multiple processors and multiple memories. The local interface 718 may use additional systems designed for coordinating communication such as load balancing, bulk data transfer, and similar systems.

While the flowcharts presented for this technology may imply a specific order of execution, the order of execution may differ from what is illustrated. For example, the order of two more blocks may be rearranged relative to the order shown. Further, two or more blocks shown in succession may be executed in parallel or with partial parallelization. In some configurations, one or more blocks shown in the flow chart may be omitted or skipped. Any number of counters, state variables, warning semaphores, or messages might be added to the logical flow for purposes of enhanced utility, accounting, performance, measurement, troubleshooting or for similar reasons.

Some of the functional units described in this specification have been labeled as modules, in order to more particularly emphasize their implementation independence. For example, a module may be implemented as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices or the like.

Modules may also be implemented in software for execution by various types of processors. An identified module of executable code may for instance, comprise one or more blocks of computer instructions, which may be organized as an object, procedure, or function. Nevertheless, the executables of an identified module need not be physically located together, but may comprise disparate instructions stored in different locations which comprise the module and achieve the stated purpose for the module when joined logically together.

Indeed, a module of executable code may be a single instruction, or many instructions, and may even be distributed over several different code segments, among different programs, and across several memory devices. Similarly, operational data may be identified and illustrated herein within modules, and may be embodied in any suitable form and organized within any suitable type of data structure. The operational data may be collected as a single data set, or may be distributed over different locations including over different storage devices. The modules may be passive or active, including agents operable to perform desired functions.

The technology described here can also be stored on a computer readable storage medium that includes volatile and non-volatile, removable and non-removable media implemented with any technology for the storage of information such as computer readable instructions, data structures, program modules, or other data. Computer readable storage media include, but is not limited to, RAM, ROM, EEPROM, flash memory or other memory technology, CD-ROM, digital versatile disks (DVD) or other optical storage, magnetic cassettes, magnetic tapes, magnetic disk storage or other magnetic storage devices, or any other computer storage medium which can be used to store the desired information and described technology.

The devices described herein may also contain communication connections or networking apparatus and networking connections that allow the devices to communicate with other devices. Communication connections are an example of communication media. Communication media typically embodies computer readable instructions, data structures, program modules and other data in a modulated data signal such as a carrier wave or other transport mechanism and includes any information delivery media. A “modulated data signal” means a signal that has one or more of its characteristics set or changed in such a manner as to encode information in the signal. By way of example, and not limitation, communication media includes wired media such as a wired network or direct-wired connection, and wireless media such as acoustic, radio frequency, infrared, and other wireless media. The term computer readable media as used herein includes communication media.

Furthermore, the described features, structures, or characteristics may be combined in any suitable manner in one or more examples. In the preceding description, numerous specific details were provided, such as examples of various configurations to provide a thorough understanding of examples of the described technology. One skilled in the relevant art will recognize, however, that the technology can be practiced without one or more of the specific details, or with other methods, components, devices, etc. In other instances, well-known structures or operations are not shown or described in detail to avoid obscuring aspects of the technology.

Although the subject matter has been described in language specific to structural features and/or operations, it is to be understood that the subject matter defined in the appended claims is not necessarily limited to the specific features and operations described above. Rather, the specific features and acts described above are disclosed as example forms of implementing the claims. Numerous modifications and alternative arrangements can be devised without departing from the spirit and scope of the described technology.

what is claimed is:

1. A method for generating placement and routing for a netlist of an integrated circuit (IC) design, comprising:
partitioning the netlist for the IC design into subsets of cells;
prioritizing the subsets of cells;
placing a first subset of cells with a first priority in an arrangement representing the IC design;
routing wire connections between the cells of the first subset of cells;
placing a second subset of cells relative to one another and the first subset of cells in the arrangement representing the IC design; and
routing wire connections between the cells of the second subset of cells and the cells of the first subset of cells.

2. The method in accordance with claim 1, wherein placing the second subset of cells occurs after placing and routing the first subset of cells.

3. The method in accordance with claim 1, further comprising:
repeatedly placing and routing subsets of the cells with previously placed and routed subsets of cells until the arrangement is complete.

4. The method in accordance with claim 1, further comprising:
calculating an initial frequency of the IC design based on the first subset of cells prior to placing and routing the second subset of cells in order to define an upper bound frequency.

5. The method in accordance with claim 4, further comprising:
calculating a subsequent frequency of the IC design based on the first and second subsets of cells after placing and routing the second subset of cells; and
comparing the subsequent and upper bound frequencies and determining if the subsequent frequency has been degraded below a predetermined limit.

6. The method in accordance with claim 1, wherein the cost function comprises at least one of:
static time analysis (STA) derived criticality based on negative slacks;
topologically with k-means to cluster local interconnect together and identify native partitions;
common clock domain; or
input/output (IO) placement.

7. The method in accordance with claim 1, wherein the partitioning is based on machine learning (ML) with an ML classifier that ranked subsets of cells from a generated dataset of subsets of cells.

8. The method in accordance with claim 1, further comprising optimizing the arrangement by:
repeating all the steps with new subsets of cells having a different number of subsets of cells than before, subsets of cells with different sizes than before, or both, in order to define a second arrangement; and
selecting the arrangement or the second arrangement based on a fastest frequency of the arrangement or the second arrangement.

9. The method in accordance with claim 1, further comprising optimizing the arrangement by:
calculating a first frequency of the IC design based on a first arrangement after placing and routing the subsets of cells;
varying a number, a size, or both, of subsets of cells to obtain new subsets of cells with a different number of subsets of cells than before, subsets of cells with different sizes than before, or both;
placing and routing the new subsets of cells in a second arrangement;
calculating a second frequency of the IC design based on the second arrangement after placing and routing the new subsets of cells; and
selecting one of the first or second arrangements based on a fastest of the first and second frequencies.

10. The method in accordance with claim 1, further comprising optimizing the arrangement by:
calculating a cumulative frequency of the IC design based on a first arrangement after placing and routing a first subset of cells;
varying a size, a composition, or both, of the first subset of cells to obtain a new subset of cells with a different size than before, a different composition than before, or both;
placing and routing the new subset of cells;
calculating a new cumulative frequency of the IC design based on a new arrangement after placing and routing the new subset of cells; and
selecting either the first subset of cells or the new subset of cells based on a fastest of the cumulative or new cumulative frequencies.

11. The method in accordance with claim 1, further comprising:
wherein partitioning the netlist is based on a cost function;
evaluating the cost function after placing and routing one or more subsets of cells;
changing the cost function or selecting a new cost function;
re-partitioning all or some of the subsets of cells based on the changed cost function or the new cost function; and
evaluating the changed cost function or the new cost function after placing and routing one or more subsets of cells.

12. The method in accordance with claim 1, wherein the IC design comprises a field-programmable gate array (FPGA) and the cells comprise logic blocs and memory elements.

13. A method for generating placement and routing for a netlist of an integrated circuit (IC) design, comprising:
a) partitioning a netlist for the IC design into subsets of cells;
b) prioritizing the subsets of cells;
c) performing a first stepwise place-route (SPR) iteration by:
i) placing a first subset of cells relative to one another in an arrangement representing the IC design;
ii) routing wire connections between the cells of the first subset of cells; and
iii) calculating an initial frequency of the IC design based on the first subset of cells in order to define an upper bound frequency;
d) performing a second SPR iteration by:
i) placing the second subset of cells relative to one another and the first subset of cells in the arrangement representing the IC design after the placing and routing of the first subset of cells;
ii) routing wire connections between the cells of the second subset of cells and the cells of the first subset of cells; and
iii) calculating a subsequent frequency of the IC design based on the first and second subsets of cells after placing and routing the second subset of cells; and
e) comparing the subsequent and upper bound frequencies and determining if the subsequent frequency has been degraded below a predetermined limit.

14. The method in accordance with claim 13, further comprising optimizing the arrangement by:
repeating all the steps with new subsets of cells having a different number of subsets of cells than before, subsets of cells with different sizes than before, or both, defining a second arrangement; and
selecting the arrangement or the second arrangement based on a fastest frequency of the arrangement or the second arrangement.

15. The method in accordance with claim 13, further comprising optimizing the arrangement by:
calculating a first frequency of the IC design based on a first arrangement after placing and routing the subsets of cells;
varying a number, size, or both, of subsets of cells to obtain new subsets of cells with a different number of subsets of cells than before, subsets of cells with different sizes than before, or both;
placing and routing the new subsets of cells in a second arrangement;
calculating a second frequency of the IC design based on the second arrangement after placing and routing the new subsets of cells; and
selecting one of the first or second arrangements based on a fastest of the first and second frequencies.

16. The method in accordance with claim 13, further comprising optimizing the arrangement by:
calculating a cumulative frequency of the IC design based on a first arrangement after placing a first subset of cells;
varying a size, a composition, or both, of the first subset of cells to obtain a new subset of cells with a different size than before, a different composition than before, or both;
placing and routing the new subset of cells;
calculating a new cumulative frequency of the IC design based on a new arrangement after placing and routing the new subset of cells; and
selecting either the first subset of cells or the new subset of cells based on a fastest of the cumulative or new cumulative frequencies.

17. The method in accordance with claim 13, further comprising:
wherein partitioning the netlist is based on a cost function;
evaluating the cost function after placing and routing one or more subsets of cells;
changing the cost function or selecting a new cost function;
re-partitioning all or some of the subsets of cells based on the changed cost function or the new cost function; and
evaluating the changed cost function or the new cost function after placing and routing one or more subsets of cells.

18. A method for generating placement and routing for a netlist of an integrated circuit (IC) design, comprising:
a) partitioning the netlist for the IC design into subsets of cells;
b) prioritizing the subsets of cells;
c) performing a first stepwise place-route (SPR) iteration by:
i) placing a first subset of cells relative to one another in an arrangement representing the IC design; and
ii) routing wire connections between the cells of the first subset of cells;
d) performing a second SPR iteration by:
i) placing the second subset of cells relative to one another and the first subset of cells in the arrangement representing the IC design after the placing and routing of the first subset of cells; and
ii) routing wire connections between the cells of the second subset of cells and the cells of the first subset of cells;
e) calculating a final frequency of the IC design based on a completed arrangement after placing and routing the subsets of cells in order to define a first arrangement with a first final frequency;
f) repartitioning at least a portion of the netlist and varying a size, a composition, or both, of the subset of cells to obtain a new subset of cells with a different size than before, a different composition than before, or both;
g) repeating one or more of the SPR iterations with the new subset of cells in order to define a second arrangement;
h) calculating a second final frequency of the IC design based on a second arrangement after placing and routing the new subset of cells; and
i) selecting the first arrangement or the second arrangement based on a faster of the first and second final frequencies.

19. The method in accordance with claim 18, further comprising:
wherein partitioning the netlist is based on a cost function;
evaluating the cost function after placing and routing one or more subsets of cells;
changing the cost function or selecting a new cost function;
re-partitioning all or some of the subsets of cells based on the changed cost function or the new cost function; and
evaluating the changed cost function or the new cost function after placing and routing one or more subsets of cells.
